(19) United States
(12) Patent Application Publication
(10) Pub. No.: US 2001/0045643 A1
(43) Pub. Date: Nov. 29, 2001

(54) SEMICONDUCTOR DEVICE KEEPING STRUCTURAL INTEGRITY UNDER HEAT-GENERATED STRESS

(76) Inventors: YOSHITSUGU KATOH, KANAGAWA (JP); SHINYA NAKASEKO, KANAGAWA (JP); TAKASHI HOZUMI, KANAGAWA (JP)

Correspondence Address: ARMSTRONG,WESTERMAN, HATTORI,, MCLELAND & NAUGHTON, LLP, 1725 K STREET, NW, SUITE 1000, WASHINGTON, DC, 20006, US

(21) Appl. No.: 09/276,515

(22) Filed: Mar. 25, 1999

(30) Foreign Application Priority Data
Jun. 19, 1998 (JP) 10-173313

(51) Int. Cl. H01L 21/44; H01L 23/34; H01L 29/40

(52) U.S. Cl. 257/706; 438/122; 257/737; 438/613; 438/112; 257/787

(57) ABSTRACT

A semiconductor device includes an elastic member which has an adhesive contact with at least one other member. The adhesive contact forces said elastic member to stay in a deformed shape different from an original shape to which said elastic member tries to return, wherein a force generated by said elastic member trying to return to the original shape serves to counteract a heat-generated stress applied to said semiconductor device.

### BACKGROUND OF THE INVENTION

1. Field of the Invention

The present invention generally relates to semiconductor devices and a method of manufacturing semiconductor devices, and particularly relates to a semiconductor device comprised of a plurality of different materials having different thermal-expansion coefficients and a method of manufacturing the semiconductor device.

Electronic equipment such as personal computers is expected to meet the demand for increasingly sophisticated functions and increased reliability. To satisfy this demand, semiconductor devices used in the electronic equipment are also expected to achieve increased reliability.

2. Description of the Related Art

FIG. 1 is an illustrative drawing showing a semiconductor device 1 as an example of a related-art device. FIGS. 2 through 4 are illustrative drawings showing a method of manufacturing the semiconductor device 1.

As shown in FIG. 1, the semiconductor device 1 mainly includes a semiconductor device 2, a wiring board 3, a metal frame 4, a heat releasing plate 5, a sealing resin 6, and balls 7.

The wiring board 3 includes an elastic resin material and predetermined wiring patterns formed thereon. The semiconductor device 2 is mounted on the wiring board 3. Wires 8 provided between the semiconductor device 2 and the wiring board 3 establish electrical connections between the semiconductor device 2 and the wiring board 3.

On the wiring board 3, also, the metal frame 4 is provided along with the semiconductor device 2. The metal frame 4 has a device container hole 9 formed at a center thereof such that the device container hole 9 extends from the top to the bottom in the figure. The semiconductor device 2 is positioned inside the device container hole 9.

The heat releasing plate 5 is a plate-shape member formed of metal material having high heat releasing characteristics, and is mounted on the metal frame 4 to cover the device container hole 9. The sealing resin 6 is an epoxy resin, for example, and fills inside the device container hole 9. The device container hole 9 is sealed at the bottom thereof by the wiring board 3 and at the top thereof by the heat releasing plate 5. Since the sealing resin 6 fills inside the device container hole 9, the semiconductor device 2 and the wires 8 are protected by the sealing resin 6.

The balls 7 serve as external connection terminals, and are provided beneath the bottom surface of the wiring board 3. The balls 7 are connected to the wiring patterns formed on the wiring board 3, so that the balls 7 are electrically connected to the semiconductor device 2 via the wiring board 3 and the wires 8.

In the following, a method of manufacturing the semiconductor device 1 having the above configuration will be described.

In order to manufacture the semiconductor device 1, a semiconductor-device-intermediate-product forming step is performed to manufacture a semiconductor-device intermediate product 10 (hereinafter called an intermediate product). The intermediate product 10 includes at least the semiconductor device 2, the wiring board 3, the metal frame 4, and the heat releasing plate 5.

At the semiconductor-device-intermediate-product forming step, the semiconductor device 2 is mounted on the wiring board 3, and the wires 8 are formed between the semiconductor device 2 and the wiring board 3. Then, the metal frame 4 is placed on the wiring board 3 such that the device container hole 9 contains the semiconductor device 2. Further, the heat releasing plate 5 is placed on the metal frame 4 so as to cover the device container hole 9. In this manner, the intermediate product 10 is formed.

After the semiconductor-device-intermediate-product forming step, the intermediate product 10 is mounted on a cast 11 as shown in FIG. 2. A resin filling step is then performed to form the sealing resin 6.

The cast 11 includes an upper cast 12 and a lower cast 13. The upper cast 12 has a mount recess 14 formed therein, and the lower cast 13 has a mount recess 15 formed therein. The mount recess 14 has such a shape that the heat releasing plate 5 fits therein. The mount recess 15 has such a shape that the wiring board 3 fits therein.

When the intermediate product 10 is to be mounted, the upper cast 12 is moved in a direction indicated by an arrow Z2 in the figure (in an upward direction) relative to the lower cast 13. The intermediate product 10 is then inserted into the gap between the upper cast 12 and the lower cast 13, and is mounted on the lower cast 13.

As the intermediate product 10 is mounted on the lower cast 13, the upper cast 12 is moved in a direction shown by an arrow Z1 in the figure (in a downward direction), so that the cast 11 clamps the intermediate product 10 as shown in FIG. 3. With the cast 11 clamping the intermediate product 10, the sealing resin 6 is filled in the device container hole 9.

After the sealing resin 6 is filled in the device container hole 9, the upper cast 12 is moved again in the direction indicated by the arrow Z2, and the intermediate product 10 with the sealing resin 6 is removed from the cast 11. All of these processes are performed during the resin filling step.

After the resin filling step, a ball mounting step is performed to mount the balls 7 (e.g., solder balls) serving as external connection terminals beneath the bottom surface of the wiring board 3. After the steps as described above, the semiconductor device 1 is completed as shown in FIG. 1.

The wiring board 3, the metal frame 4, the heat releasing plate 5, and the sealing resin 6 of the semiconductor device 1 are made of different materials, and, thus, have different thermal-expansion coefficients. Because of this, heat generated by the semiconductor device 2 during an operation thereof or changes in ambient temperature of the semiconductor device 1 may cause warping of the semiconductor device 1 due to differences in the thermal-expansion coefficients.

Thermal-expansion coefficients of the sealing resin 6, the metal frame 4, and the wiring board 3 will be denoted as A, B, and C, respectively, in the following. Since a relation B<A<C is generally observed, a stress as shown by an arrow F1 in FIG. 1 is applied to the semiconductor device 1 due to differences in the thermal-expansion coefficients. This results in the wiring board 3 being warped as shown by dotted lines.

With warping of the semiconductor device 1, it is possible that all the balls 7 cannot be contacted to an assembly board when the semiconductor device 1 is mounted on the assembly board. This leads to less reliable implementation of the semiconductor device 1. Also, there is a risk of breaking off between the semiconductor device 2 and the wiring board 3 and/or between the wiring board 3 and the metal frame 4, so that the semiconductor device 1 itself has a less reliable structure.

Accordingly, there is a need for a semiconductor device which can suppress warping thereof caused by a temperature change so as to enhance reliability of the device, and there is also a need for a method of manufacturing such a semiconductor device.

### SUMMARY OF THE INVENTION

Accordingly, it is a general object of the present invention to provide a semiconductor device which can satisfy the need described above.

It is another and more specific object of the present invention to provide a semiconductor device which can suppress warping thereof caused by a temperature change so as to enhance reliability of the device.

In order to achieve the above objects, a semiconductor device (or an electronic part) according to the present invention includes an elastic member which has an adhesive contact with at least one other member, the adhesive contact forcing said elastic member to stay in a deformed shape different from an original shape to which said elastic member tries to return, wherein a force generated by said elastic member trying to return to the original shape serves to counteract a heat-generated stress applied to said semiconductor device (or an electronic part).

According to one aspect of the present invention, a semiconductor device includes a semiconductor chip, a wiring board which carries said semiconductor chip, a frame member mounted on said wiring board and having a device container hole which stores said semiconductor chip therein, a sealing resin filled in the device container hole to cover said semiconductor chip, and a plate-shape member mounted on said frame member on an opposite side to where said wiring board is situated, said plate-shape member covering the device container hole, wherein one of said frame member and said plate-shape member is kept in a deformed shape, and generates a force by trying to return from the deformed shape to an original shape, said force being applied to said sealing resin and said wiring board in a direction toward said plate-shape member.

In the semiconductor device described above, a heat-generated stress, which is caused by differences in thermal-expansion coefficients between individual elements making up the semiconductor device, is canceled or counteracted by the force generated by the elastic member trying to return to its original shape. This prevents warping of the semiconductor device.

It is yet another object of the present invention to provide a method of manufacturing a semiconductor device which can suppress warping thereof caused by a temperature change so as to enhance reliability of the device.

In order to achieve the above object, a method of forming a semiconductor device according to the present invention includes the steps of a) forming a semiconductor intermediate product by assembling an elastic member with other components, b) deforming said elastic member from an original shape to a deformed shape by clamping the semiconductor intermediate product with a cast, c) filling resin in the semiconductor intermediate product while said elastic member is in the deformed shape, said elastic member making an adhesive contact with the filled resin, and d) releasing the clamping, wherein the adhesive contact forces said elastic member to stay in the deformed shape.

According to one aspect of the present invention, the method as described above is such that said step a) includes the steps of mounting a semiconductor chip on a wiring board, mounting a frame member on the wiring board, the frame member having a device container hole formed at a center thereof to contain the semiconductor chip therein, and mounting said elastic member on the frame member to cover the device container hole. Further, the step c) fills the resin in the device container hole.

In the semiconductor device formed by the method described above, a heat-generated stress, which is caused by differences in thermal-expansion coefficients between individual elements making up the semiconductor device, is canceled or counteracted by the force generated by the elastic member trying to return to its original shape. This prevents warping of the semiconductor device.

Other objects and further features of the present invention will be apparent from the following detailed description when read in conjunction with the accompanying drawings.

### BRIEF DESCRIPTION OF THE DRAWINGS

FIG. 1 is an illustrative drawing showing a semiconductor device as an example of a related-art device;

FIGS. 2 through 4 are illustrative drawings showing a method of manufacturing the semiconductor device of FIG. 1;

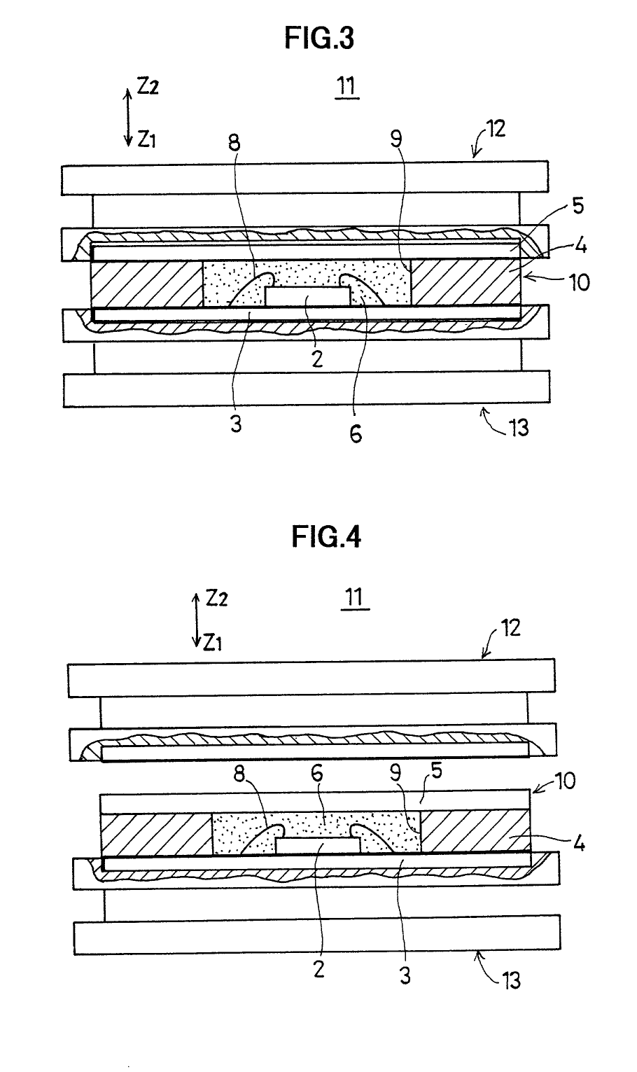

FIG. 5 is a cross-sectional view of a semiconductor device according to an embodiment of the present invention;

FIGS. 6 through 10 are illustrative drawings for explaining a method of manufacturing the semiconductor device of FIG. 5 according to an embodiment of the present invention;

FIG. 11 is an illustrative drawing showing an intermediate product of a first variation;

FIGS. 12A and 12B are illustrative drawings showing an intermediate product of a second variation and a heat releasing plate of the intermediate product of the second variation, respectively;

FIGS. 13A and 13B are illustrative drawings showing an intermediate product of a third variation and a heat releasing plate of the intermediate product of the third variation, respectively;

FIGS. 14A and 14B are illustrative drawings showing an intermediate product of a fourth variation and a heat releasing plate of the intermediate product of the fourth variation, respectively;

FIGS. 15A and 15B are illustrative drawings showing an intermediate product of a fifth variation and a heat releasing plate of the intermediate product of the fifth variation, respectively;

FIG. 16 is an illustrative drawing showing an intermediate product of a sixth variation;

FIG. 17 is an illustrative drawing showing an intermediate product of a seventh variation; and

FIG. 18 is an illustrative drawing showing an intermediate product of an eighth variation.

### DESCRIPTION OF THE PREFERRED EMBODIMENTS

In the following, embodiments of the present invention will be described with reference to the accompanying drawings.

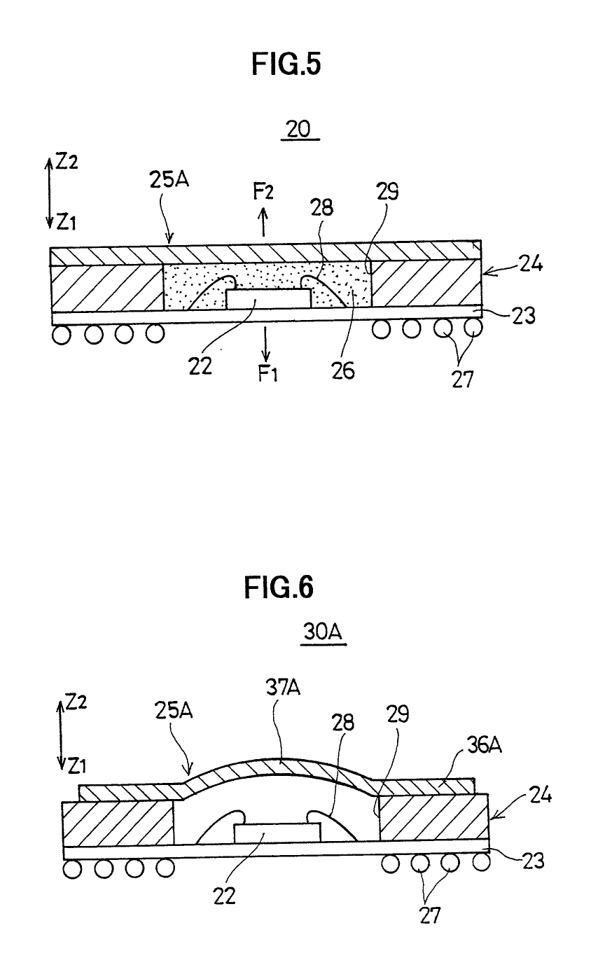

FIG. 5 is a cross-sectional view of a semiconductor device 20 according to an embodiment of the present invention.

The semiconductor device 20 mainly includes a semiconductor device 22, a wiring board 23, a metal frame (frame member) 24, a heat releasing plate (plate member) 25A, sealing resin 26, and balls 27.

The wiring board 23 includes an insulator resin film (e.g., made of polyimide) and predetermined wiring patterns (e.g., made of copper sheets) formed thereon. The wiring board 23 generally has a thermal-expansion coefficient of 26 ppm.

The semiconductor device 22 is mounted on the wiring board 23. Wires 28 are provided by a wire-bonding device between the semiconductor device 22 and the wiring board 23, and establish electrical connections between the semiconductor device 22 and the wiring board 23. Rather than using the wires 28, bumps may be formed on the semiconductor device 22, and may be connected to the wiring board 23 via flip-chip bonding.

On the wiring board 23, also, the metal frame 24 is provided along with the semiconductor device 22. The metal frame 24 is made of copper, for example, and has a thermal-expansion coefficient of 18 ppm. The metal frame 24 has a device container hole 29 formed at a center thereof such that the device container hole 29 extends from the top to the bottom in the figure. With the metal frame 24 mounted on the wiring board 23, the semiconductor device 22 is situated inside the device container hole 29.

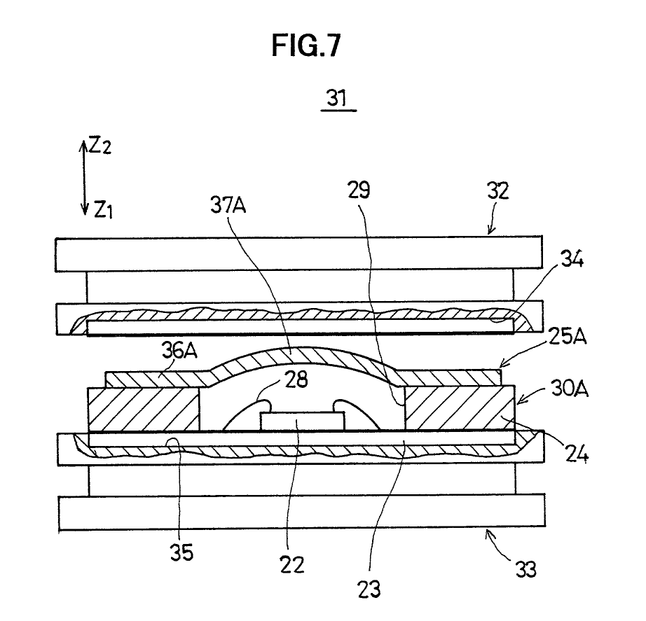

The heat releasing plate 25A is a plate-shape member formed of metal material having elastically deformable characteristics, and is mounted on the metal frame 24. The heat releasing plate 25A has a flat-plate shape as shown in FIG. 5 when manufacturing of the semiconductor device 20 is completed. An original shape of the heat releasing plate 25A, however, is curved, and have a protrusion portion 37A protruding outwardly (i.e., toward a direction shown by an arrow Z2) as shown in FIG. 6.

The protrusion portion 37A is deformed via a manufacturing process which will be described later, creating a flat plate as shown in FIG. 5. In the completed semiconductor device 20, therefore, the heat releasing plate 25A has an elastic restoration force stored therein. That is, a force that works to return the heat releasing plate 25A to its original shape is constantly present. This elastic restoration force is applied in a direction shown by the arrow Z2 in the figure. Hereinafter, the force that works to return the heat releasing plate 25A to its original shape is referred to as an elastic restoration force F2.

In the present embodiment, a material used for the heat releasing plate 25A not only has such elasticity as described above but also has sufficient heat-releasing characteristics (e.g., may be copper, which is the same material as that of the metal frame 24). Heat generated when the semiconductor device 22 operates is thus released via the heat releasing plate 25A, resulting in better heat-releasing characteristics of the semiconductor device 20. Details about the heat releasing plate 25A having the elastic restoration force stored therein will not be described here, but will be described later in detail for the sake of convenience of explanation.

The sealing resin 26 fills inside the device container hole 29 formed through the metal frame 24. The sealing resin 26 may be an epoxy resin, and has a thermal-expansion coefficient thereof adjusted to be close to the thermal-expansion coefficient of the semiconductor device 22. Such an adjustment is made by controlling the amount of filler mixed in the epoxy resin. In practice, the thermal-expansion coefficient of the sealing resin 26 is about 20 ppm.

The device container hole 29 is sealed at the bottom thereof by the wiring board 23 and at the top thereof by the heat releasing plate 25. Since the sealing resin 26 fills a space contained by the device container hole 29, the wiring board 23, and the heat releasing plate 25A, the semiconductor device 22 and the wires 28 are protected by the sealing resin 26.

The balls 27 serve as external connection terminals of the semiconductor device 20, and are formed from solder, for example. The balls 27 are provided beneath the bottom surface of the wiring board 23, and are electrically connected to the wiring patterns formed on the insulator-resin film via holes (not shown) formed through the insulator-resin film. In this manner, the balls 27 are electrically connected to the semiconductor device 22 via the wiring board 23 and the wires 28.

In the following, ramifications of thermal-expansion coefficients of components forming the semiconductor device 20 will be described.

As previously described, the semiconductor device 20 of the present invention is comprised of several different components made of different materials. In detail, the wiring board 23 is formed from a polyimide insulator resin and copper sheets. The metal frame 24 and the heat releasing plate 25A are formed from copper. The sealing resin 26 is formed from an epoxy resin. Since these components 23, 24, 25A, and 26 are made of different materials, they have different thermal-expansion coefficients.

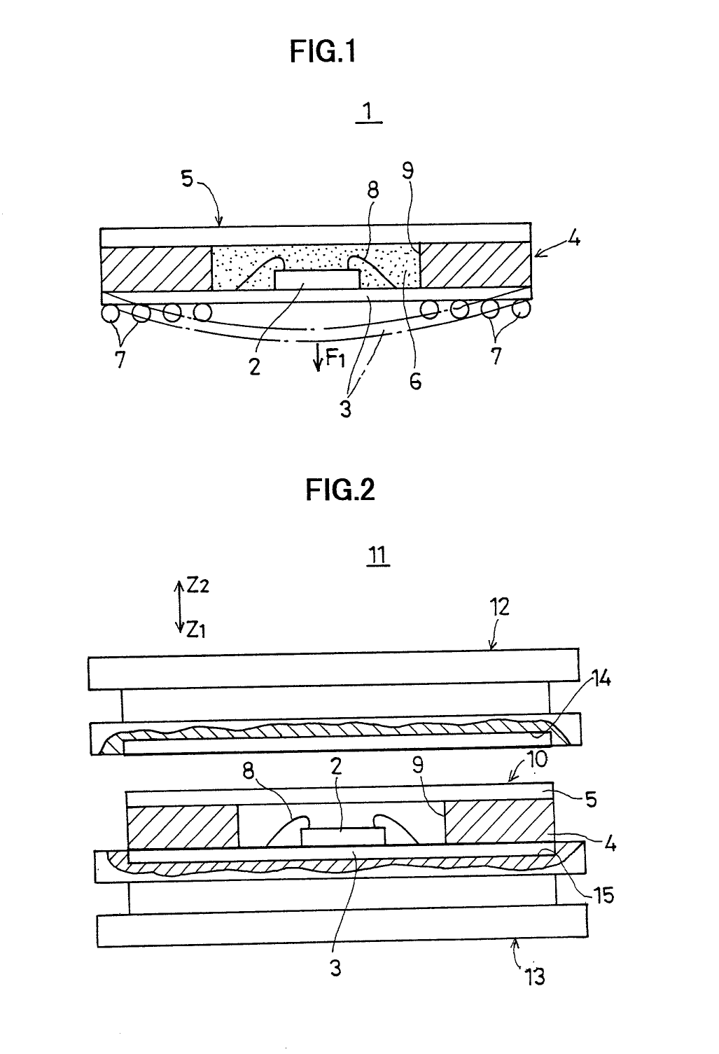

Heat generated from the semiconductor device 22 during operation thereof and changes in ambient temperature of the semiconductor device 20 generate stress to the semiconductor device 20 because of differences of the thermal-expansion coefficients. Here, thermal-expansion coefficients of the sealing resin 26, the metal frame 24, and the wiring board 23 are denoted as A (20 ppm), B (18 ppm), and C (26 ppm), respectively. Since a relation B<A<C is observed, a heat-generated stress as shown by an arrow F1 in FIG. 5 is applied to the semiconductor device 20. In the case of the semiconductor device 1 of the related art, the heat-generated stress F1 resulted in such warping as shown by dotted lines in FIG. 1.

In the semiconductor device 20 of the present invention, the heat releasing plate 25A is made of elastically deformable material, and stores therein an elastic restoration force. Further, as shown in FIG. 5, the heat-generated stress F1 is applied in a direction shown by the arrow Z1, and the elastic restoration force F2 is applied in a direction shown by the arrow Z2. That is, the heat-generated stress F1 and the elastic restoration force F2 are opposed to each other.

The sealing resin 26 has adhesive contact with the wiring board 23 and the heat releasing plate 25A. The elastic restoration force F2 thus urges the sealing resin 26 and the wiring board 23 toward the direction of the arrow Z2 relative to the metal frame 24. In such an arrangement, the heat-generated stress F1 caused by a temperature rise is canceled by the elastic restoration force F2 in the semiconductor device 20. This prevents warping of the semiconductor device 20.

Since warping is prevented, all the balls 27 can be reliably connected to an assembly board regardless of temperature changes when the semiconductor device 20 is implemented on the assembly board. This can enhance reliable implementation of the semiconductor device 20. Also, breaking off is prevented between the semiconductor device 22 and the wiring board 23 and/or between the wiring board 23 and the metal frame 24. This increase reliability of the semiconductor device 20.

In what follows, a method of manufacturing the semiconductor device 20 will be described.

FIGS. 6 through 10 are illustrative drawings for explaining a method of manufacturing the semiconductor device 20 according to an embodiment of the present invention.

In order to manufacture the semiconductor device 20, a semiconductor-device-intermediate-product forming step is performed to manufacture a semiconductor-device intermediate product 30A (hereinafter called an intermediate product). FIG. 6 shows an intermediate product 30A formed by the semiconductor-device-intermediate-product forming step. Here, the intermediate product 30A includes at least the semiconductor device 22, the wiring board 23, the metal frame 24, and the heat releasing plate 25.

At the semiconductor-device-intermediate-product forming step, the semiconductor device 22 is mounted on the wiring board 23 with an adhesive having an insulating characteristic. Then, the wires 28 are formed between the semiconductor device 22 and the wiring board 23. A wire-bonding device well known in the art is used for forming the wires 28.

After mounting the semiconductor device 22 on the wiring board 23, the metal frame 24 is fixedly mounted on the wiring board 23. An adhesive is used for this purpose. When the metal frame 24 having the device container hole 29 formed therethrough is mounted on the wiring board 23, relative positioning is attended to before establishing adhesive contacts such that the semiconductor device 22 is situated inside the device container hole 29.

After the metal frame 24 is mounted on the wiring board 23, the heat releasing plate 25A is placed on the metal frame 24. The heat releasing plate 25A includes a perimeter portion 36A at a circumference thereof and the protrusion portion 37A at a center area thereof which corresponds to the area of the device container hole 29. The protrusion portion 37A projects towards a direction shown by the arrow Z2. In the present embodiment, the protrusion portion 37A has a dome shape.

The heat releasing plate 25A having a configuration as described above is just placed on the metal frame 24, and is not fixed by such means as adhesive. In order to insure relative positioning between the device container hole 29 and the protrusion portion 37A, a positioning mechanism (such as positioning pins and positioning holes) many be provided for the heat releasing plate 25A and the metal frame 24. In the manner as described above, the intermediate product 30A is formed.

After the semiconductor-device-intermediate-product forming step described above, a protrusion deforming step is performed next.

At the protrusion deforming step, the intermediate product 30A is mounted on a cast 31 as shown in FIG. 7. The cast 31 includes an upper cast 32 and a lower cast 33. The upper cast 32 has a mount recess 34 formed therein, and the lower cast 33 has a mount recess 35 formed therein. The cast 31 thus has a cast structure of a cavity-less type. The mount recess 34 and the mount recess 35 has a flat surface without any surface terrain.

When the intermediate product 30A is to be mounted, the upper cast 32 is moved in a direction indicated by an arrow Z2 in the figure (in an upward direction) relative to the lower cast 33, as shown in FIG. 7. The intermediate product 30A is then inserted into the gap between the upper cast 32 and the lower cast 33, and is mounted on the lower cast 33. At this point, the protrusion portion 37A of the heat releasing plate 25A of the intermediate product 30A is facing the flat surface of the mount recess 34 of the upper cast 32.

As the intermediate product 30A is mounted on the lower cast 33, the upper cast 32 is moved in a direction shown by an arrow Z1 in the figure (in a downward direction), so that the cast 31 clamps the intermediate product 30A as shown in FIG. 8. Through this process, the protrusion portion 37A projecting towards the direction of the arrow Z2 is pressed downward (in the direction of the arrow Z1) by the upper cast 32 (the mount recess 34), so that the protrusion portion 37A is elastically deformed, collapsing toward the device container hole 29.

With the cast 31 clamping the intermediate product 30A, the heat releasing plate 25A is kept in a flat shape. In this position, an elastic restoration force trying to return to the original shape (i.e., the shape of FIG. 7) is generated by the heat releasing plate 25A.

After completing the protrusion deforming step, a resin filling step is performed. At the resin filling step, resin is filled in the device container hole 29 to form the sealing resin 26. This step is carried out while the cast 31 is clamping the intermediate product 30A, i.e., while the elastic restoration force is stored in the heat releasing plate 25A.

A process for filling resin is disclosed in Japanese Laid-open Patent Application No.7-221132, and this process may be employed to from the sealing resin 26. The resin filling process of this document is able to form the sealing resin 26 having a desired shape without providing cavity in the upper cast 32. This makes it possible to reduce investment in equipment by lowering a cost of the casts. Further, since there is no need to provide a casting-off member, reliability is enhanced with regard to shaping of resin.

After the sealing resin 26 is filled in the device container hole 29, the upper cast 32 is moved again in the direction indicated by the arrow Z2 as shown in FIG. 9, and the intermediate product 30A with the sealing resin 26 is removed from the cast 31. The sealing resin 26 functions as adhesive, so that the wiring board 23 and the heat releasing plate 25A are adhesively attached to the sealing resin 26.

The heat releasing plate 25A elastically deformed remains in the deformed shape because of the adhesive contact with the sealing resin 26. That is, the heat releasing plate 25A remains to have the elastic restoration force stored therein. In this manner, the protrusion deforming step and the resin filling step are successively performed to easily form the heat releasing plate 25A having the elastic restoration force stored therein.

After the resin filling step, a ball mounting step is performed. At the ball mounting step, as shown in FIG. 10, the balls 27 (e.g., solder balls) are provided beneath the wiring board 23 of the intermediate product 30A so as to serve as external connection terminals. The wiring board 23 has holes formed therethrough at positions where the balls 27 are arranged, so that the balls 27 are electrically connected to the wiring patterns via these holes. At such positions as the balls 27 are provided beneath the wiring board 23, the metal frame 24 is in existence on the other side of the wiring board 23. The metal frame 24 thus serves as a backing member to help to mount the balls 27 easily and reliably. After the steps as described above, the semiconductor device 20 is completed as shown in FIG. 5.

The semiconductor device 20 manufactured according to the embodiment of the present invention includes the heat releasing plate 25A, which has the elastic restoration force F2 stored therein so that the force F2 is constantly applied in the direction shown by the arrow Z2. The elastic restoration force F2 serves to cancel the heat-generated stress F1 when the stress F1 is applied to the semiconductor device 20 due to differences in the thermal-expansion coefficients. This prevents warping of the semiconductor device 20 in a reliable fashion.

In the above embodiment, the heat releasing plate 25A has an elastic restoration force stored therein. Alternatively, the metal frame 24 may be designed to have an elastic restoration force stored therein. A circumferential surface of the metal frame 24 and an inner surface of the device container hole 29 may be provided with grooves, for example, and these grooves may b used for generating elastic force in either upward or downward direction (in the directions shown by the arrows Z1 and Z2). This configuration can achieve the same results as the above-described embodiment.

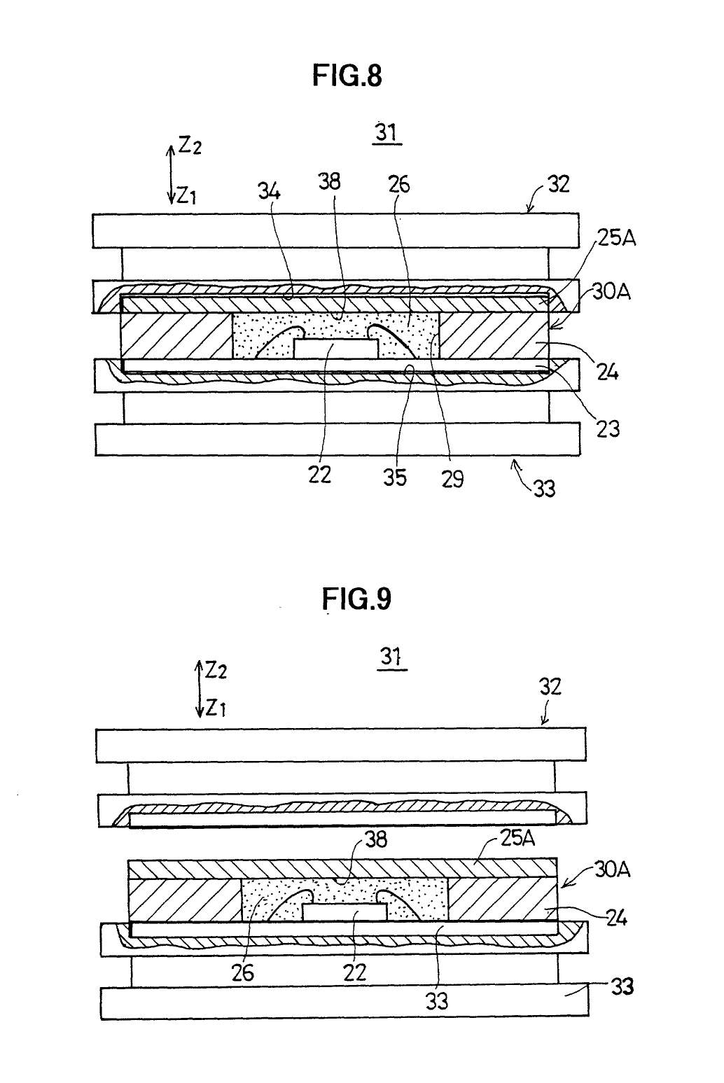

FIGS. 11 through 18 are illustrative drawings showing variations of the intermediate product according to the present invention. In FIGS. 11 through 18, the same elements as those of the embodiment described above with reference to FIGS. 5 through 10 are referred to by the same numerals, and a description thereof will be omitted.

FIG. 11 is an illustrative drawing showing an intermediate product 30B of a first variation. In the intermediate product 30B, a heat releasing plate 25B includes a perimeter portion 36B and a protrusion portion 37B, which has a cross-sectional shape of a trapezoid.

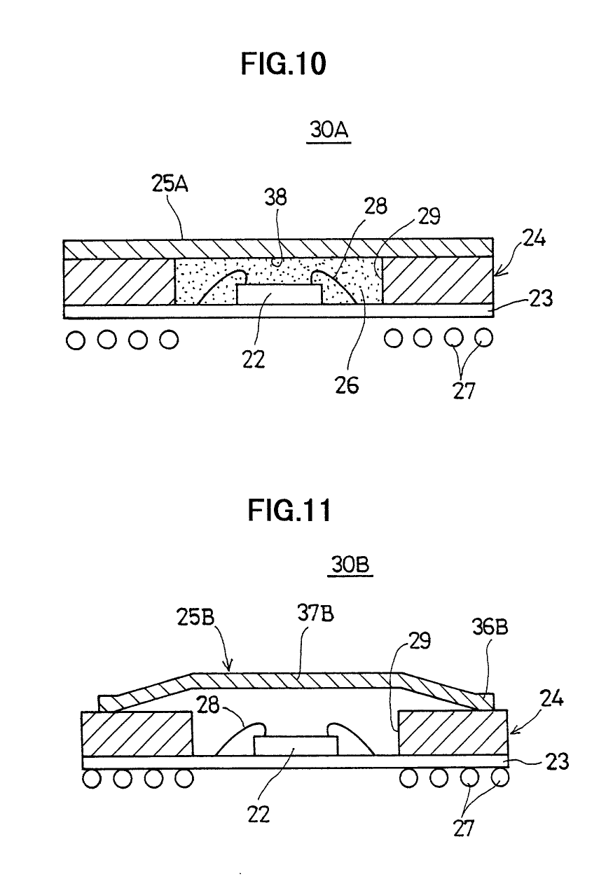

FIGS. 12A and 12B are illustrative drawings showing an intermediate product 30C of a second variation and a heat releasing plate 25C of the intermediate product 30C, respectively. In the intermediate product 30C, the heat releasing plate 25C includes a perimeter portion 36C and a protrusion portion 37C, which has a cross-sectional shape of a triangle.

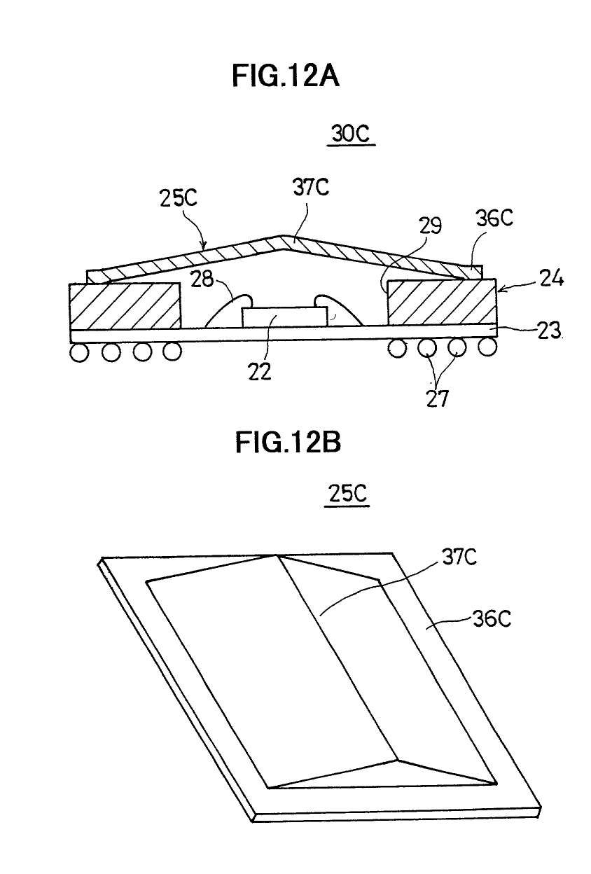

FIGS. 13A and 13B are illustrative drawings showing an intermediate product 30D of a third variation and a heat releasing plate 25D of the intermediate product 30D, respectively. In the intermediate product 30D, the heat releasing plate 25D includes a perimeter portion 36D and a protrusion portion 37D, which has a pyramid shape.

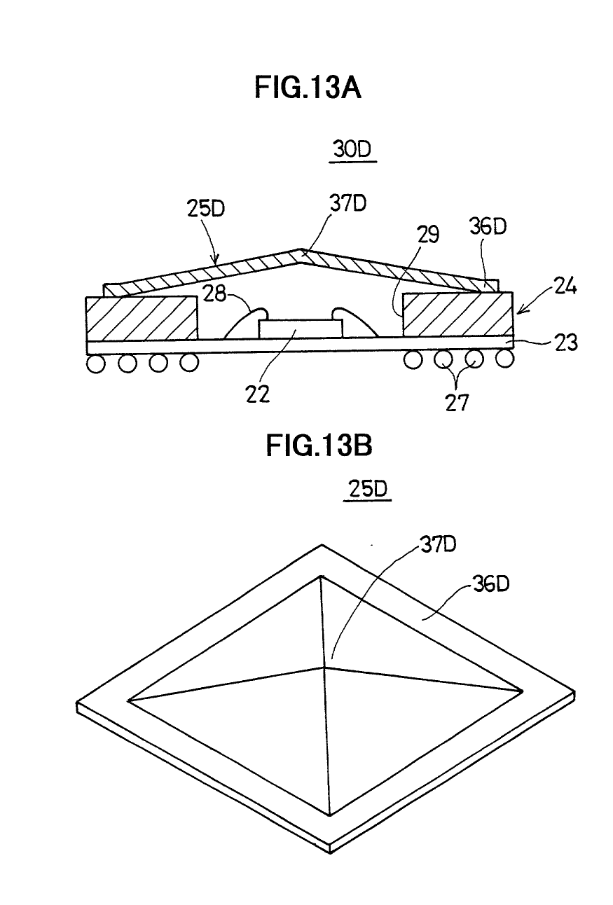

FIGS. 14A and 14B are illustrative drawings showing an intermediate product 30E of a fourth variation and a heat releasing plate 25E of the intermediate product 30E, respectively. In the intermediate product 30E, the heat releasing plate 25E includes a perimeter portion 36E and a protrusion portion 37E, which has a rectangular-parallelepiped shape.

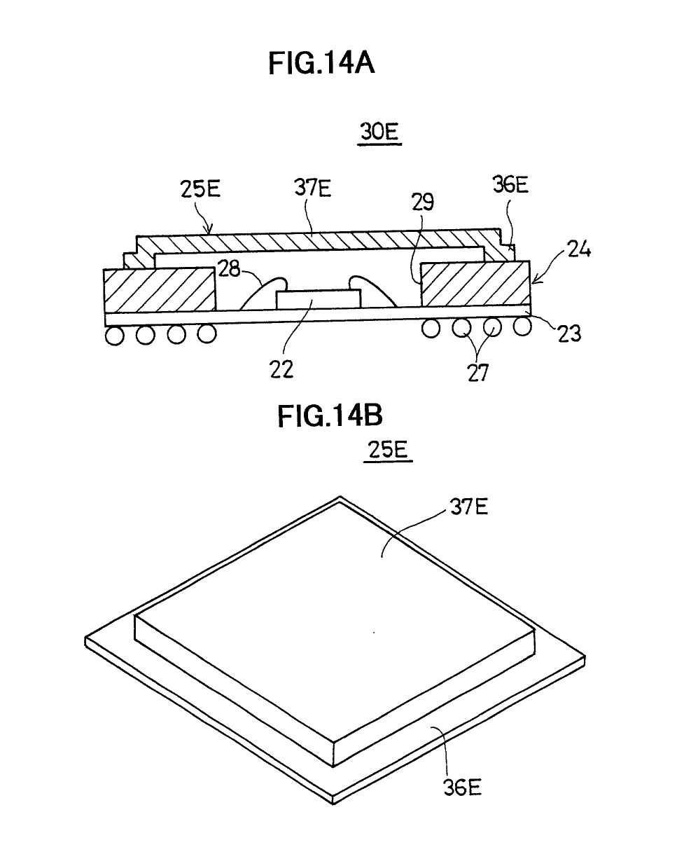

FIGS. 15A and 15B are illustrative drawings showing an intermediate product 30F of a fifth variation and a heat releasing plate 25F of the intermediate product 30F, respectively. In the intermediate product 30F, the heat releasing plate 25F includes a perimeter portion 36F and a protrusion portion 37F, which has a circular-cylinder shape.

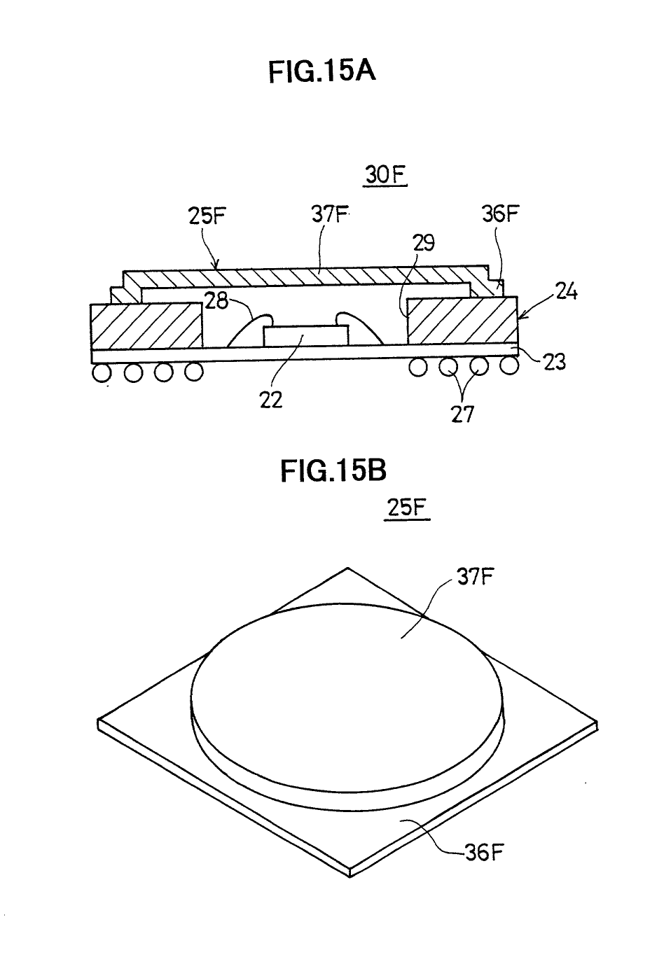

FIG. 16 is an illustrative drawing showing an intermediate product 30G of a sixth variation. In the intermediate product 30G, a heat releasing plate 25G includes a perimeter portion 36G and a protrusion portion 37G, which has a plurality of protrusions.

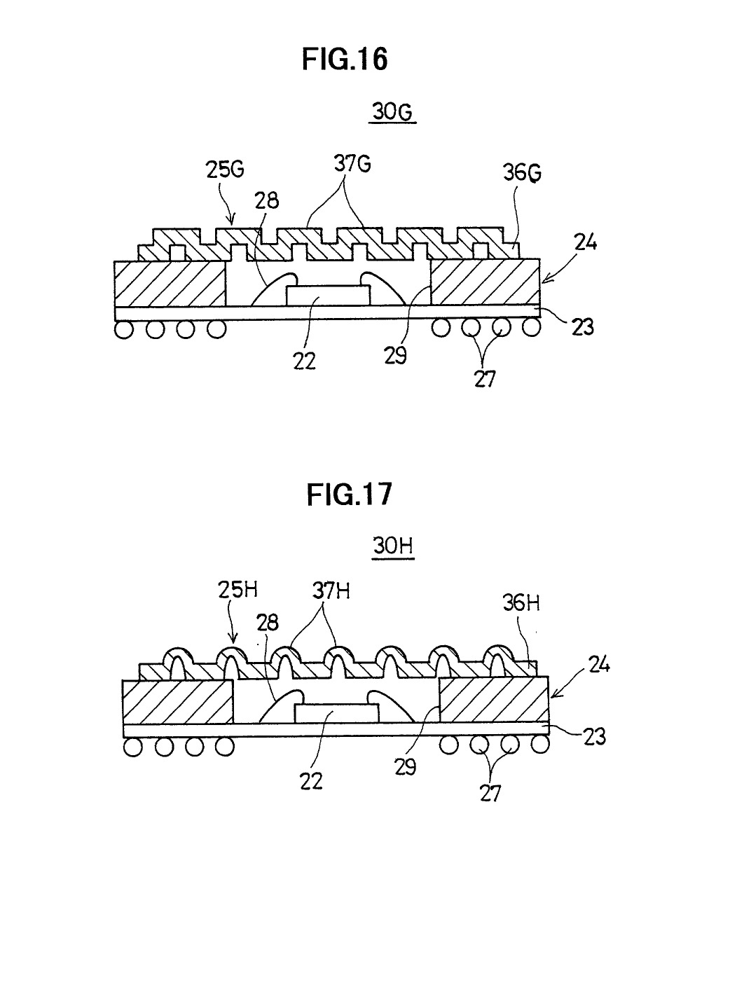

FIG. 17 is an illustrative drawing showing an intermediate product 30H of a seventh variation. In the intermediate product 30H, a heat releasing plate 25H includes a perimeter portion 36H and a protrusion portion 37H, which has a plurality of protrusions having a dimple shape.

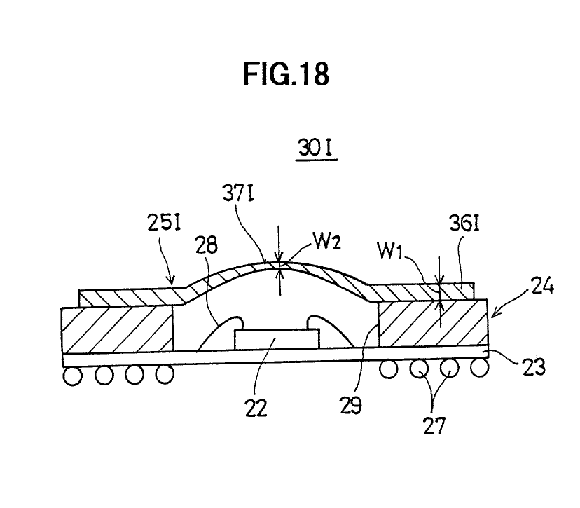

FIG. 18 is an illustrative drawing showing an intermediate product 30I of an eighth variation. A heat releasing plate 25I includes a perimeter portion 36I and a protrusion portion 37I inside the perimeter portion 36I. The protrusion portion 37I has a dome shape, and has a thickness thereof getting thinner towards a center top of the dome. As shown in FIG. 18, a thickness W2 at the center of the protrusion portion 37I is thinner than a thickness W1 of the perimeter portion 36I.

Any one of the intermediate products 30B through 30I described above as variations can achieve the same object as the intermediate product 30A which has been described with reference to FIGS. 4 through 10. Namely, use of any one of the intermediate products 30B through 30I can prevent warping of the semiconductor device manufactured from the intermediate product.

Further, the intermediate products 30G and 30H shown in FIG. 16 and FIG. 17, respectively, have an increased surface area, which enhances a heat releasing characteristic.

Moreover, the intermediate product 30I of the eighth variation shown in FIG. 18 has the protrusion portion 37I of a varying thickness. Adjustment of the thickness makes it possible to adjust the elastic restoration force F2, so that a force appropriate for canceling the heat-generated stress F1 is readily generated. This prevents the elastic restoration force F2 from serving as an excess stress exceeding the heat-generated force F1.

A configuration of the heat releasing plate is not limited to the embodiment and variations described above, but any configuration and any shape of protrusion portion can be employed as long as an elastic restoration force is generated after a protrusion portion is deformed. For example, the protrusion portion may have a triangular-pyramid shape.

The semiconductor device formed according to the present invention includes a SAW filter. In the case of a SAW filter, however, no resin sealing is performed.

Further, the present invention is not limited to these embodiments, but various variations and modifications may be made without departing from the scope of the present invention.

The present application is based on Japanese priority application No.10-173313 filed on Jun. 19, 1998, with Japanese Patent Office, the entire contents of which are hereby incorporated by reference.

What is claimed is:

1. An electronic part comprising an elastic member which has an adhesive contact with at least one other member, the adhesive contact forcing said elastic member to stay in a deformed shape different from an original shape to which said elastic member tries to return, wherein a force generated by said elastic member trying to return to the original shape serves to counteract a heat-generated stress applied to said electronic part.

2. A semiconductor device comprising:
a semiconductor chip;
a wiring board which carries said semiconductor ship;
a frame member mounted on said wiring board and having a device container hole which stores said semiconductor chip therein;
a sealing resin filled in the device container hole to cover said semiconductor chip; and
a plate-shape member mounted on said frame member on an opposite side to where said wiring board is situated, said plate-shape member covering the device container hole,
wherein one of said frame member and said plate-shape member is kept in a deformed shape, and generates a force by trying to return from the deformed shape to an original shape, said force being applied to said sealing resin and said wiring board in a direction toward said plate-shape member.

3. The semiconductor device as claimed in claim 2, a thermal-expansion coefficient of said sealing resin is greater than a thermal-expansion coefficient of said frame member, and is smaller than a thermal-expansion coefficient of said wiring board.

4. The semiconductor device as claimed in claim 2, wherein said plate-shape member has an adhesive contact with said sealing resin, the adhesive contact forcing said plate-shape member to stay in the deformed shape.

5. The semiconductor device as claimed in claim 2, wherein said plate-shape member has a perimeter portion at a circumference thereof and a protrusion portion at a center thereof, the protrusion portion in the original shape projecting from a flat position relative to the perimeter portion, said protrusion portion having the adhesive contact with said sealing resin and being forced by the adhesive contact to stay in the flat position.

6. The semiconductor device as claimed in claim 5, wherein the protrusion portion has a thickness thereof becoming thinner towards a center thereof.

7. The semiconductor device as claimed in claim 2, wherein said plate-shape member is made of a material suitable for releasing heat.

8. A method of forming a semiconductor device, comprising the steps of:
a) forming a semiconductor intermediate product by assembling an elastic member with other components;
b) deforming said elastic member from an original shape to a deformed shape by clamping the semiconductor intermediate product with a cast;
c) filling resin in the semiconductor intermediate product while said elastic member is in the deformed shape, said elastic member making an adhesive contact with the filled resin; and
d) releasing the clamping, wherein the adhesive contact forces said elastic member to stay in the deformed shape.

9. The method as claimed in claim 8, wherein said step a) includes the steps of:
mounting a semiconductor chip on a wiring board;
mounting a frame member on the wiring board, the frame member having a device container hole formed at a center thereof to contain the semiconductor chip therein; and
mounting said elastic member on the frame member to cover the device container hole.

10. The method as claimed in claim 9, wherein said step c) fills the resin in the device container hole.
